(19) United States
(12) Patent Application Publication
(10) Pub. No.: US 2009/0134382 A1
(43) Pub. Date: May 28, 2009

(54) MULTILEVEL LOGIC BALLISTIC DEFLECTION TRANSISTOR

(75) Inventors: Slavek P. Aksamit, Austin, TX (US); David D. Chudy, Raleigh, NC (US); Cristian Medina, Durham, NC (US)

Correspondence Address: CAREY, RODRIGUEZ, GREENBERG & PAUL, LLP;STEVEN M. GREENBERG, 950 PENINSULA CORPORATE CIRCLE, SUITE 3020, BOCA RATON, FL, 33487, US

(73) Assignee: INTERNATIONAL BUSINESS MACHINES CORPORATION, Armonk, NY (US)

(21) Appl. No.: 11/945,825

(22) Filed: Nov. 27, 2007

(51) Int. Cl. H01L 29/08

(52) U.S. Cl. 257/27; 257/E29.04

(57) ABSTRACT

A multilevel logic transistor including a ballistic channel, the ballistic channel formed in a substrate layer and configured to receive a flow of electrons generated by an emitter, a deflection barrier, the deflection barrier comprising at least two deflection surfaces and a deflection channel, and a deflection controller, the deflection controller configured to generate an electrical biasing field for directing the flowed of electrons, wherein the deflection barrier is positioned in the ballistic channel such that the deflection barrier is in the path of the received electrons. The multilevel logic transistor can further include an electron spin controller configured to generate a particular spin on each electron in the flow of electrons.

### BACKGROUND OF THE INVENTION

1. Statement of the Technical Field

The present invention relates, in general, to high frequency semiconductor devices operating in the terahertz frequencies and more particularly to multilevel logic transistors which utilize ballistic electron phenomena and spintronics to obtain improved efficiency and higher frequency operation than has previously been available.

2. Description of the Related Art

While modern transistor technology has many more years of useful life in everyday computing use, it is starting to reach its limits in terms of raw speed. As transistors become both smaller and more powerful, researchers have to find ever more creative ways to deal with the inherent problems that come with the small sizes demanded by today's applications. As researchers continue to scale down the sizes and ramp up the speed of transistors, heat generation and electrical leaking become larger and larger problems.

The basic idea behind all transistors is that they actively control the flow of electrons. Traditional transistors are a sandwich of two materials; the center material is controlled via current/voltage so as to either permit electrons to flow across the sandwich, or to halt their flow across the sandwich. It is the starting and stopping of electrons that causes great amounts of energy, typically in the form of heat, to be released.

A traditional transistor registers a “one” as a collection of electrons on a capacitor, and a “zero” when those electrons are removed. Moving electrons on and off the capacitor is analogous to filling and emptying a bucket of water. One drawback to this method is that it takes time to fill and empty that bucket. That refill-time limits the speed of the transistor and with the transistors in today's laptops operating at approximately two gigahertz, this equates to approximately two billion refills every second. A second drawback is that these transistors produce immense amounts of heat when that energy is emptied.

Currently, some researchers propose a special chip that will use the ballistic trajectory of an electron to register a “one” or a “zero”, like a game of atomic bumper pool. A transistor as shown in FIG. 1 is known as a Ballistic Deflection Transistor (BDT). As shown in FIG. 1, the BDT transistor includes a lower pair of structures 102 and 104 which can be disposed on a substrate. The lower pair of structures 102 and 104 can define a channel 106 between them. Each structure 102, 104 includes a deflection controller 108, 110. The deflection controllers 108 and 110 are used for generating a small electrical field that steers or pushes electrons slightly to the left or right of a nano-deflector 112. The BDT transistor further includes an upper pair of structures 114, 116. The upper left structure 114 and the lower left structure 102 are positioned such that a channel 118 is defined between them. The upper right structure 116 and the lower right structure 104 are positioned such that a channel 120 is defined between them.

In many ways, the BDT transistor 100 of FIG. 1 can be described as a road intersection, with a downward pointing triangular median in the intersection. An electron would enter from the lower end of channel 106 and pass through an electric field, which would divert it ever so slightly, to the right or left, once it hits the triangular median it would be re-directed in a new direction. In this design, a flow of electrons to the right would register as a one and a flow of electrons to the left would register as a zero. The BDT design should also be able to resist much of the electrical noise present in all electronic devices because the noise would only be present in the electrical “steering” field, and calculations show the variations of the noise would cancel themselves out as the electron passes through.

This current BDT transistor design is limited to a single switch configuration, which provides classical logic (0 or 1) and therefore is limited to single level logic device.

### SUMMARY OF THE INVENTION

The present invention addresses the deficiencies of the art with respect to transistors, and provides a novel and non-obvious apparatus for multilevel logic transistor performance. In one embodiment of the invention, A multilevel logic transistor including a ballistic channel, the ballistic channel formed in a substrate layer and configured to receive a flow of electrons generated by an emitter, a deflection barrier, the deflection barrier comprising at least two deflection surfaces and a deflection channel, and a deflection controller, the deflection controller configured to generate an electrical biasing field for directing the flowed of electrons, and where the deflection barrier is positioned in the ballistic channel such that the deflection barrier is in the path of the received electrons. The multilevel logic transistor can further include an electron spin controller configured to generate a particular spin on each electron in the flow of electrons.

Additional aspects of the invention will be set forth in part in the description which follows, and in part will be obvious from the description, or may be learned by practice of the invention. The aspects of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The accompanying drawings, which are incorporated in and constitute part of this specification, illustrate embodiments of the invention and together with the description, serve to explain the principles of the invention. The embodiments illustrated herein are presently preferred, it being understood, however, that the invention is not limited to the precise arrangements and instrumentalities shown, wherein:

FIG. 1 is a block diagram illustrating a conventional Ballistic Deflection Transistor (BDT);

FIG. 2 is block diagram illustrating a multilevel logic transistor according to a first preferred embodiment of the present invention;

FIG. 3 is block diagram illustrating a multilevel logic transistor according to a second preferred embodiment of the present invention; and

FIG. 4 is block diagram illustrating an audio/video circuit using the multilevel logic transistor of FIG. 3 as a 1 to 3 switch according to a second preferred embodiment of the present invention.

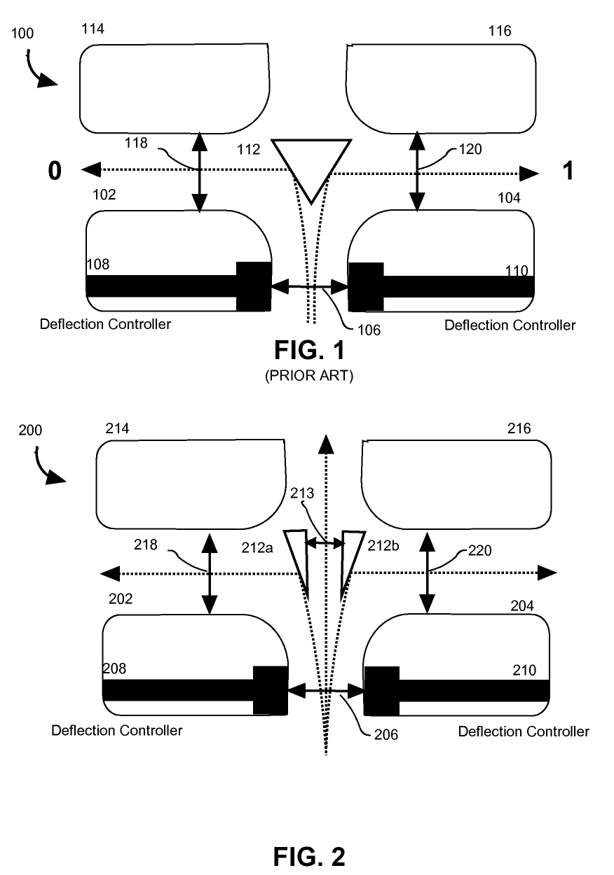

### DETAILED DESCRIPTION OF THE INVENTION

Embodiments of the present invention provide an apparatus for an ultra high frequency semiconductor device. In an embodiment of the invention, a multilevel logic transistor including a ballistic channel, the ballistic channel formed in a substrate layer and configured to receive a flow of electrons generated by an emitter, a deflection barrier, the deflection barrier including at least two deflection surfaces and a deflection channel, and a deflection controller. The deflection controller can generate an electrical biasing field for directing the flow of electrons. The deflection barrier is positioned in the ballistic channel such that the deflection barrier is in the path of the received flow of electrons. The multilevel logic transistor can further include an electron spin controller configured to generate a particular spin on each electron in the flow of electrons.

In illustration, FIG. 2 is block diagram illustrating a multilevel logic transistor 200. As shown in FIG. 2, the multilevel logic transistor 200 includes a lower pair of structures 202 and 204 that can be disposed on a substrate. The lower pair of structures 202 and 204 can define a channel 206 between them. Each structure 202, 204 includes a deflection controller 208, 210, respectively. The deflection controllers 208 and 210 are used for generating a small electrical field that steers or pushes electrons as needed. A positive voltage differential will deflect the electron in one direction and a negative differential in the other, while a zero differential will guide the electron through the middle channel 213 of the nano-deflector 212. As shown in FIG. 2, the nano-deflector geometry may be represented by two deflection portions 212a, 212b and the middle channel 213. Each of the deflection portions 212a, 212b can include deflection surfaces, which cause an electron to deflect into one of the side channels 218 and 220. Thus, by forming a channel 213 in the middle of the nano-deflector 212, an electron can flow through the barrier of the nano-deflector 212 and exit through a separate terminal in the BDT transistor. This modified nano-deflector 212 advantageously provides an additional logic level and the BDT transistor becomes a three state device. The multilevel transistor 200 further includes an upper pair of structures 214, 216. The upper left structure 214 and the lower left structure 202 are positioned such that a channel 218 is defined between them. The upper right structure 216 and the lower right structure 204 are positioned such that a channel 220 is defined between them. In operation, the multilevel transistor 200 can provide switching speeds estimated to be in the terahertz range.

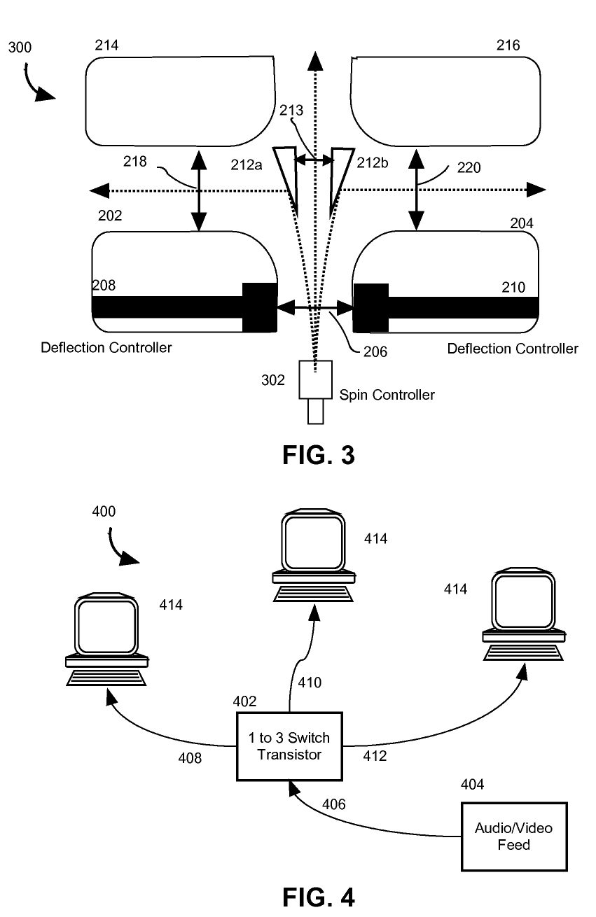

In further illustration of a multilevel logic transistor, FIG. 3 is block diagram illustrating a multilevel logic transistor 300 according to a second preferred embodiment. In this embodiment, the multilevel logic transistor 300 further includes a pair of electron spin controllers 302 as part of the emitter of a flow of electrons into the ballistic channel 206. The remaining portions of FIG. 3 function in a similar way to the correspondingly numbered portions of FIG. 2 and that description will not be repeated with respect to FIG. 3.

In general, spintronics or “spin-based electronics”, also known as magnetoelectronics, is an emerging technology which exploits the quantum spin states of electrons as well as making use of their charge state. The electron spin itself is manifested as a two state magnetic energy system, where the two states are referred to as an “up” state and a “down” state.

Applying spintronics to the multilevel logic transistor of FIG. 2, each of the three outputs of the multilevel logic transistor of FIG. 3 will now have two corresponding states as provided by the electron spin. This advantageously provides for a complete switch function, e.g., a “one” or a “zero”, at each of the three outputs of the multilevel logic transistor for a total of six states. Consequently, the modified transistor in this embodiment functions as a complete one to three switching device.

In further illustration, FIG. 4 is block diagram illustrating an audio/video system 400 employing the multilevel logic transistor of FIG. 3 as a 1 to 3 switch according to a second preferred embodiment of the present invention. In system 400, a multilevel logic transistor 402, e.g., the multilevel logic transistor of FIG. 3, functions as a 1-to-3 switch or multiplexer. In this embodiment, the multilevel logic transistor 402 receives the output 406 from Audio/Video Feed 404. A series of computing devices 414 are in communication with the three outputs 408, 410 and 412 of multilevel logic transistor 402. Each of the computing devices 414 can receive the output 406 from Audio/Video Feed 404 via multilevel logic transistor 402.

The present invention can be realized in hardware, software, or a combination of hardware and software. An implementation of the method and system of the present invention can be realized in a centralized fashion in one computer system or in a distributed fashion where different elements are spread across several interconnected computer systems. Any kind of computer system, or other apparatus adapted for carrying out the methods described herein, is suited to perform the functions described herein.

A typical combination of hardware and software could be a general-purpose computer system with a computer program that, when being loaded and executed, controls the computer system such that it carries out the methods described herein. The present invention can also be embedded in a computer program product, which comprises all the features enabling the implementation of the methods described herein, and which, when loaded in a computer system is able to carry out these methods.

Embodiments of the invention can take the form of an entirely hardware embodiment, an entirely software embodiment or an embodiment containing both hardware and software elements. In a preferred embodiment, the invention is implemented in software, which includes but is not limited to firmware, resident software, microcode, and the like. Furthermore, the invention can take the form of a computer program product accessible from a computer-usable or computer-readable medium providing program code for use by or in connection with a computer or any instruction execution system.

For the purposes of this description, a computer-usable or computer readable medium can be any apparatus that can contain, store, communicate, propagate, or transport the program for use by or in connection with the instruction execution system, apparatus, or device. The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk-read only memory (CD-ROM), compact disk-read/write (CD-R/W) and DVD.

Computer program or application in the present context means any expression, in any language, code or notation, of a set of instructions intended to cause a system having an information processing capability to perform a particular function either directly or after either or both of the following a) conversion to another language, code or notation; b) reproduction in a different material form. Significantly, this invention can be embodied in other specific forms without departing from the spirit or essential attributes thereof, and accordingly, reference should be had to the following claims, rather than to the foregoing specification, as indicating the scope of the invention.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution. Input/output or I/O devices (including but not limited to keyboards, displays, pointing devices, etc.) can be coupled to the system either directly or through intervening I/O controllers. Network adapters may also be coupled to the system to enable the data processing system to become coupled to other data processing systems or remote printers or storage devices through intervening private or public networks. Modems, cable modem and Ethernet cards are just a few of the currently available types of network adapters.

1. A multilevel logic transistor, the transistor comprising:
a ballistic channel, the ballistic channel formed in a substrate layer and configured to receive a flow of electrons generated by an emitter;
a deflection barrier, the deflection barrier comprising at least two deflection surfaces and a deflection channel; and
a deflection controller, the deflection controller configured to generate an electrical biasing field for directing the flowed of electrons, wherein
the deflection barrier is positioned in the ballistic channel such that the deflection barrier is in the path of the received electrons,
the deflection controller selectively directs the flow of electrons to one of three outputs.

2. A multilevel logic transistor, the transistor comprising:
a ballistic channel, the ballistic channel formed in a substrate layer and configured to receive a flow of electrons generated by an emitter;
a deflection barrier, the deflection barrier comprising at least two deflection surfaces and a deflection channel; and
a deflection controller, the deflection controller configured to generate an electrical biasing field for directing the flowed of electrons, wherein the deflection barrier is positioned in the ballistic channel such that the deflection baffler is in the path of the received electrons
wherein the emitter further comprising an electron spin controller, the spin controller configured to generate a particular spin on each electron in the flow of electrons.

3. The device of claim 2, wherein the transistor comprises a pair of spin controller.

4. The device of claim 2, wherein the deflection controller selectively directs the flow of electrons to one of three outputs.

5. The device of claim 1, wherein the transistor is a 1-to-3 switch.

6. The device of claim 2, wherein the transistor is a 1-to-3 switch.
